(19) United States
(12) Patent Application Publication
(10) Pub. No.: US 2019/0086794 A1
(43) Pub. Date: Mar. 21, 2019

(54) IMPRINT APPARATUS AND METHOD OF MANUFACTURING DISPLAY PANEL

(71) Applicant: SAMSUNG ELECTRONICS CO., LTD., Suwon-si (KR)

(72) Inventors: Ho YU, Pohang-si (KR); Myoung-soo CHOI, Hwaseong-si (KR); Dong-wook KIM, Seoul (KR); Jung-wook KIM, Seongnam-si (KR); Ki-ju SOHN, Gunpo-si (KR); Sung-kyu LEE, Yongin-si (KR); Eun-soo HWANG, Seoul (KR)

(21) Appl. No.: 15/942,795

(22) Filed: Apr. 2, 2018

(30) Foreign Application Priority Data
Sep. 19, 2017 (KR) 10-2017-0120510

(51) Int. Cl. G03F 7/00; B29C 33/38; B29C 43/58; B29C 43/36; B29C 43/50

(52) U.S. Cl. CPC G03F 7/0002; B29C 33/3878; B29C 43/58; B29L 2031/3475; B29C 43/3697; B29C 43/50; B29C 2043/5808; B29C 43/36

(57) ABSTRACT

An imprint apparatus including a stage supporting a stamp master on which a master pattern for forming a stamping pattern on a flexible substrate is formed, or a substrate on which a pattern corresponding to the stamping pattern is formed by contact with the stamping pattern; a roll-to-roll mover to move the flexible substrate along a path adjacent to the stage; a clamp including a front clamp that secures a first portion of the flexible substrate, and a rear clamp that secures a second portion of the flexible substrate spaced apart from the first portion; a pressure roller to press the flexible substrate so that the flexible substrate secured by the clamp is brought into contact with the substrate or the stamp master; and a clamp driving controller to drive the clamp to adjust tension between the first portion and the second portion.

### CROSS-REFERENCE TO RELATED APPLICATION

Korean Patent Application No. 10-2017-0120510, filed on Sep. 19, 2017, in the Korean Intellectual Property Office, and entitled: “Imprint Apparatus and Method of Manufacturing Display Panel,” is incorporated by reference herein in its entirety.

### BACKGROUND

### 1. Field

Embodiments relate to an imprint apparatus and a method of manufacturing a display panel.

### 2. Description of the Related Art

Nanoimprint lithography is a patterning technique that may replace photolithography and electron-beam lithography. In a nanoimprint process, when a resin that is curable by a light source of a specific wavelength is coated on a substrate and then pressed by a mold having a reverse shape of a pattern desired to be fabricated, the resin having fluidity may fill an empty space of the mold due to capillarity. The resin may be cured by light irradiation, followed by removing the mold, thereby forming the pattern on the substrate. In a process of fabricating a semiconductor device, a pattern formed by a nanoimprint process may be used as a sacrificial layer, e.g., an etch mask, for a subsequent process.

### SUMMARY

The embodiments may be realized by providing an imprint apparatus including a stage, the stage supporting a stamp master on which a master pattern for forming a stamping pattern on a flexible substrate is formed, or a substrate on which a pattern corresponding to the stamping pattern is formed by contact with the flexible substrate having the stamping pattern; a roll-to-roll mover configured to move the flexible substrate along a path adjacent to the stage; a clamp, the clamp including a front clamp that secures a first portion of the flexible substrate, and a rear clamp that secures a second portion of the flexible substrate, the second portion being spaced apart from the first portion in a length direction of the flexible substrate; a pressure roller configured to press the flexible substrate so that the flexible substrate secured by the clamp is brought into contact with the substrate or the stamp master; and a clamp driving controller configured to drive the clamp to adjust tension between the first portion and the second portion.

The embodiments may be realized by providing an imprint apparatus including a stage supporting a substrate having a pattern region; a roll-to-roll mover configured to move a flexible substrate along a path adjacent to the stage; a front clamp arranged adjacent to one end of the pattern region and securing a first portion of the flexible substrate; and a rear clamp arranged adjacent to the other end of the pattern region opposite to the one end of the pattern region and securing a second portion of the flexible substrate, the second portion being spaced apart from the first portion, wherein the front clamp includes a guide extending downwardly to guide the flexible substrate to a position adjacent to the one end of the pattern region.

The embodiments may be realized by providing an imprint apparatus including a roll-to-roll unwinder/rewinder configured to unwind or rewind a flexible substrate; a stage arranged under the flexible substrate supported by the roll-to-roll unwinder/rewinder, the stage supporting a stamp master, on which a master pattern for forming a stamping pattern on the flexible substrate is formed, or a substrate, which is brought into contact with the flexible substrate having the stamping pattern formed thereon so that a pattern corresponding to the stamping pattern is formed on the substrate; a front clamp securing a first end of a region of the flexible substrate; a rear clamp securing a second end of the region of the flexible substrate, the second end being opposite to the first end; and a pressure roller configured to press the flexible substrate while moving between the first end and the second end so that the flexible substrate is brought into contact with the substrate or the stamp master, wherein, in correspondence with the movement of the pressure roller, the front clamp securing the first end is fixed at a certain position, and the rear clamp securing the second end is moved upwardly or downwardly

The embodiments may be realized by providing a method of manufacturing a display panel, the method including preparing a flexible substrate on which a stamping pattern is formed; preparing a substrate, which has a first material film and a first resin layer on the first material film, and performing an imprint process for forming a pattern corresponding to the stamping pattern on the first resin layer; and removing a portion of the first material film by using the first resin layer on which the pattern is formed, wherein the imprint process includes arranging the substrate on a stage, and providing the stamping pattern over the substrate by unwinding or rewinding the flexible substrate by a roll-to-roll mover supporting the flexible substrate; securing a first portion of the flexible substrate by a front clamp and securing a second portion of the flexible substrate by a rear clamp, the second portion being spaced apart from the first portion in a length direction of the flexible substrate; and forming the pattern corresponding to the stamping pattern on the first resin layer by sequentially bringing the flexible substrate into contact with the substrate along a first direction, and wherein forming the pattern includes adjusting tension between the first portion and the second portion by driving the front clamp and the rear clamp.

### BRIEF DESCRIPTION OF THE DRAWINGS

Features will be apparent to those of skill in the art by describing in detail exemplary embodiments with reference to the attached drawings in which:

FIGS. 1A and 1B illustrate schematic diagrams of an imprint apparatus according to some embodiments;

FIG. 2 illustrates a perspective view of a substrate and a flexible substrate that is secured by a clamp, during an imprint process in the imprint apparatus shown in FIG. 1B;

FIG. 3 illustrates a schematic diagram of an imprint apparatus according to some embodiments;

FIG. 4 illustrates a perspective view of a stamp master and a flexible substrate that is secured by a clamp, during a mold stamp process in the imprint apparatus shown in FIG. 3;

FIG. 5 illustrates a schematic diagram of a portion of the imprint apparatus shown in FIGS. 1A and 1B.

FIGS. 6A and 6B illustrate schematic diagrams of a portion of an imprint apparatus according to some embodiments;

FIG. 7 illustrates a perspective view of a substrate and a flexible substrate that is secured by a clamp, in the imprint apparatus shown in FIG. 6B;

FIG. 8 illustrates a flowchart of a film stamp process for forming a stamping pattern on a flexible substrate by using an imprint apparatus according to some embodiments;

FIGS. 9A to 9E illustrate diagrams showing stages in a film stamp process using an imprint apparatus according to some embodiments;

FIG. 10 illustrates a flowchart of an imprint process for transferring a stamping pattern of a flexible substrate to a substrate by using an imprint apparatus according to some embodiments;

FIGS. 11A to 11E illustrate diagrams showing stages in an imprint process using an imprint apparatus according to some embodiments;

FIGS. 12A and 12B illustrate diagrams of stages in a method of operating an imprint apparatus according to some embodiments; and

FIGS. 13A to 13G illustrate cross-sectional views of stages in a method of manufacturing a display panel, according to some embodiments.

### DETAILED DESCRIPTION

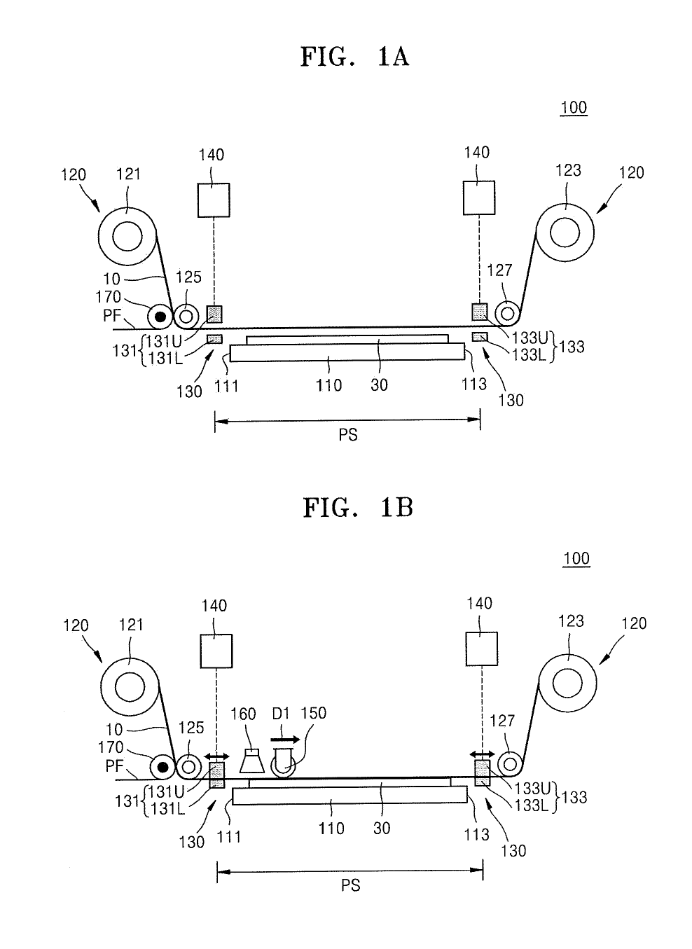

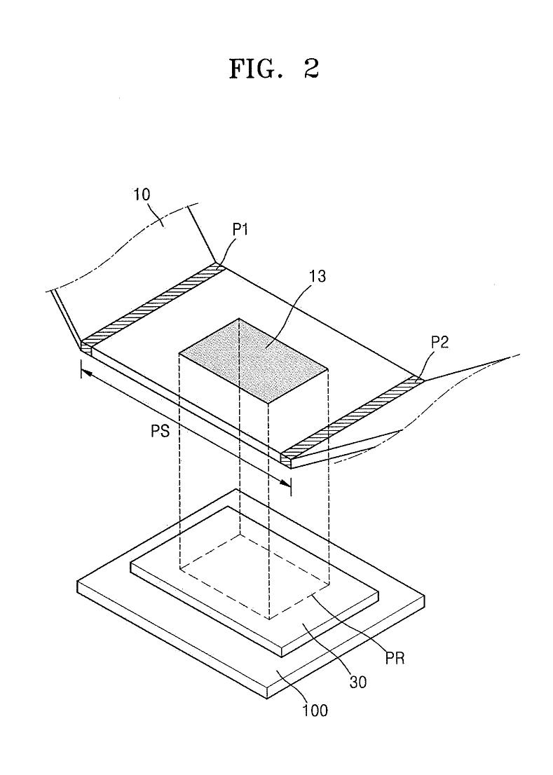

FIGS. 1A and 1B illustrate schematic diagrams of an imprint apparatus 100 according to some embodiments. FIG. 2 illustrates a perspective view of a substrate 30 and a flexible substrate 10 that is secured by a clamp 130, during an imprint process in the imprint apparatus 100 shown in FIG. 1B. FIG. 1A illustrates the imprint apparatus 100 when the clamp 130 for securing the flexible substrate 10 is opened, and FIG. 1B illustrates the imprint apparatus 100 when the flexible substrate 10 is secured by the clamp 130. In FIG. 2, the flexible substrate 10 and the substrate 30 are separately illustrated for convenience.

Referring to FIGS. 1A to 2, the imprint apparatus 100 may include a stage 110, a roll-to-roll member or roll-to-roll mover 120, the clamp 130, a clamp driving controller 140, a pressure roller 150, and a curing member or curer 160. In an implementation, the imprint apparatus 100 may perform an imprint process for transferring a stamping pattern 13 of the flexible substrate 10 to the substrate 30 that is a pattern transfer object.

The stage 110 may support the substrate 30 during the imprint process.

The roll-to-roll mover (e.g., roll-to-roll unwinder/rewinder) 120 may support the flexible substrate 10, and may move the flexible substrate 10 by unwinding or rewinding operations. The roll-to-roll mover 120 may move the flexible substrate 10 along a path adjacent to the stage 110.

The roll-to-roll mover 120 may include a flexible substrate supplying roll 121, around which one end of the flexible substrate 10 is wound, and a flexible substrate recovering roll 123, around which the other end of the flexible substrate 10 is wound. The flexible substrate supplying roll 121 may include a roll, around which the one end of the flexible substrate 10 is wound, and a rotation shaft that may rotate the roll and thus unwind or rewind the flexible substrate 10.

On a moving path of the flexible substrate 10 provided by the roll-to-roll mover 120, a first guide roller 125 (for guiding movement of the flexible substrate 10 between the flexible substrate supplying roll 121 and the stage 110) and a second guide roller 127 (for guiding movement of the flexible substrate 10 between the stage 110 and the flexible substrate recovering roll 123) may be mounted. By the roll-to-roll mover 120 and the first and second guide rollers 125 and 127, the flexible substrate 10 may be moved along a certain path facing a surface of the stage 110.

The flexible substrate 10 may include a polymer film, e.g., polycarbonate, polyethylene terephthalate, polyethylene naphthalene, or polyimde, or may include thin glass. A SiOx film, a SiNx film, or the like may be formed on a surface of the flexible substrate 10, and the surface of the flexible substrate 10 may undergo a surface treatment for the imprint process or the like. One surface of the flexible substrate 10 may be covered with a protective film PF.

A protective film removing unit or protective film remover 170 may be arranged between the flexible substrate supplying roll 121 and the stage 110. The protective film remover 170 may remove the protective film PF from the flexible substrate 10 before the flexible substrate 10 is supplied to the stage 110.

The clamp 130 may be arranged adjacent to the stage 110 and may secure the flexible substrate 10. The clamp 130 may include a front clamp 131, which is arranged adjacent to one end 111 of the stage 110 and secures a first portion P1 of the flexible substrate 10, and a rear clamp 133, which is arranged adjacent to the other end 113 of the stage 110 opposite to the one end 111 of the stage 110 and secures a second portion P2 of the flexible substrate 10. The second portion P2 of the flexible substrate 10, which is secured by the rear clamp 133, may be spaced apart from the first portion P1 of the flexible substrate 10, which is secured by the front clamp 131, in a lengthwise (e.g., moving) direction of the flexible substrate 10. When the imprint process is performed, a region of the flexible substrate 10 between the first portion P1 and the second portion P2 may refer to a region in which the stamping pattern 13 is formed.

The front clamp 131 may include a first upper body 131U and a first lower body 131L, which are spaced apart from each other with the flexible substrate 10 therebetween. The first upper body 131U and the first lower body 131L may be configured in the manner of being openable and closable with respect to each other to be switchable between a closed position for securing the first portion P1 of the flexible substrate 10 and an open position for allowing unwinding or rewinding of the flexible substrate 10 by the roll-to-roll mover 120. In an implementation, each of the first upper body 131U and the first lower body 131L may have a shape extending in a widthwise direction of the flexible substrate 10 (e.g., orthogonal to the moving direction of the flexible substrate 10).

The rear clamp 133 may include a second upper body 133U and a second lower body 133L, which are spaced apart from each other with the flexible substrate 10 therebetween. The second upper body 133U and the second lower body 133L may be configured in the manner of being openable and closable with respect to each other to be switchable between a closed position for securing the second portion P2 of the flexible substrate 10 and an open position allowing unwinding or rewinding of the flexible substrate 10 by the roll-to-roll mover 120. In an implementation, each of the second upper body 133U and the second lower body 133L may have a shape extending in the widthwise direction of the flexible substrate 10.

In an implementation, each of the front clamp 131 and the rear clamp 133 may be a magnetic clamp.

As the first portion P1 and the second portion P2 of the flexible substrate 10 are respectively secured by the front clamp 131 and the rear clamp 133, tension between the first portion P1 and the second portion P2 may be completely separated from tension formed ahead with reference to the first portion P1 and tension formed behind with reference to the second portion P2. For example, the tension of the flexible substrate 10 between the flexible substrate supplying roll 121 and the front clamp 131, the tension of the flexible substrate 10 between the front clamp 131 and the rear clamp 133, and the tension of the flexible substrate 10 between the rear clamp 133 and the flexible substrate recovering roll 123 may be separated from each other. For example, the tension between the first portion P1 secured by the front clamp 131 and the second portion P2 secured by the rear clamp 133 may be formed regardless or independently of the tension applied to the flexible substrate 10 by the roll-to-roll member 120, and the tension between the first portion P1 and the second portion P2 may be determined by the clamp 130.

By tension separation by the clamp 130, a significantly low level of tension may be applied to the flexible substrate 10 in a process section PS. For example, the tension applied between the first portion P1 and the second portion P2 may be less than the tension applied to the flexible substrate 10 by the roll-to-roll member 120. Therefore, according to an embodiment, problems which could otherwise be caused when more tension than is needed is applied between the first portion P1 and the second portion P2, e.g., a problem of distortion of a transferred pattern due to deformation of the flexible substrate 10, and a problem of detachment of the flexible substrate 10 from the substrate 30 before completion of pattern transfer without being maintained in contact with the substrate 30, may be reduced and/or prevented.

The clamp driving controller 140 may control driving of the front clamp 131 and the rear clamp 133. In an implementation, the clamp driving controller 140 may drive the front clamp 131 and the rear clamp 133 so that a diversity of tension required depending upon process conditions is applied between the first portion P1 and the second portion P2.

In an implementation, the clamp driving controller 140 may adjust the tension applied between the first portion P1 and the second portion P2 by moving at least one of the front clamp 131 (securing the first portion P1 of the flexible substrate 10) and the rear clamp 133 (securing the second portion P2 of the flexible substrate 10). For example, the front clamp 131 and the rear clamp 133 may be configured to be moved in a direction parallel to a main surface of the stage 110 and/or a direction perpendicular to the main surface of the stage 110 while securing the flexible substrate 10. For example, as shown in FIG. 1B, the tension between the first portion P1 and second portion P2 may be increased or reduced by horizontally moving the front clamp 131 and/or the rear clamp 133 (e.g., as indicated by the bold, double-headed arrows).

In an implementation, to adjust the tension between the first portion P1 and second portion P2, while the front clamp 131 is fixed at a certain position, a position of the rear clamp 133 may be changed. In an implementation, to adjust the tension between the first portion P1 and second portion P2, positions of both of the front clamp 131 and the rear clamp 133 may be changed.

In other apparatuses, to adjust the tension of the flexible substrate 10, tension of a whole section of the flexible substrate 10 supported by the roll-to-roll mover 120 has been adjusted. In this case, alignment of a plurality of rolls or rollers mounted on a moving path of the flexible substrate 10 has been required to be preceded. However, according to an embodiment, the tension of the flexible substrate 10 (e.g., only) within the process section PS may be adjusted by using the clamp 130, and a desired level of tension may be more easily applied to the flexible substrate 10 within the process section PS even without alignment of the plurality of rolls or rollers.

The pressure roller 150 may be mounted above the stage 110 and may bring the flexible substrate 10 into contact with the substrate 30 by pressing the flexible substrate 10 during the imprint process. The pressure roller 150 may be connected to a driving device such as a linear actuator to be moved along a surface of the stage 110.

The pressure roller 150 may sequentially press the flexible substrate 10 while moving in a first direction D1 from the one end 111 of the stage 110 toward the other end 113 of the stage 110. For example, the pressure roller 150 may sequentially bring the flexible substrate 10 into contact with the substrate 30 while moving in the first direction D1. As the flexible substrate 10 is sequentially brought into contact with the substrate 30 by the pressure roller 150, air flowing between the flexible substrate 10 and the substrate 30 during a film stamp process or the imprint process may be discharged to the other end 113 of the stage 110 along the first direction D1.

In addition, as the flexible substrate 10 is removed from the substrate 30, the pressure roller 150 may be moved in an opposite direction to the first direction D1 and simultaneously guide the flexible substrate 10 so that the flexible substrate 10 is sequentially removed from the substrate 30.

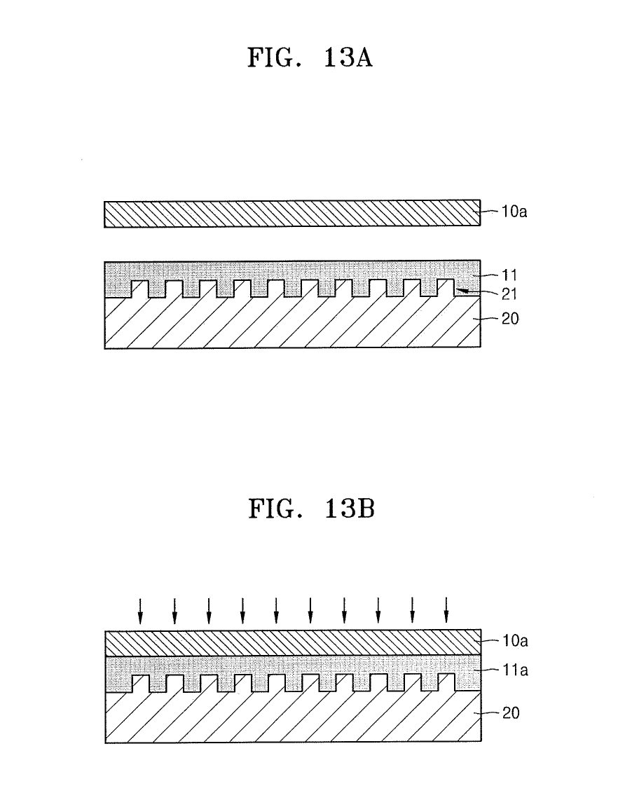

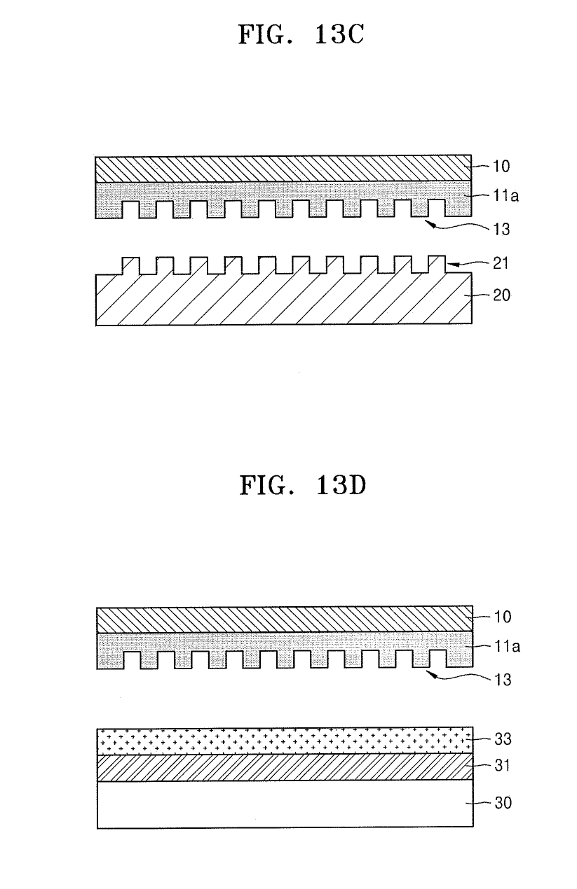

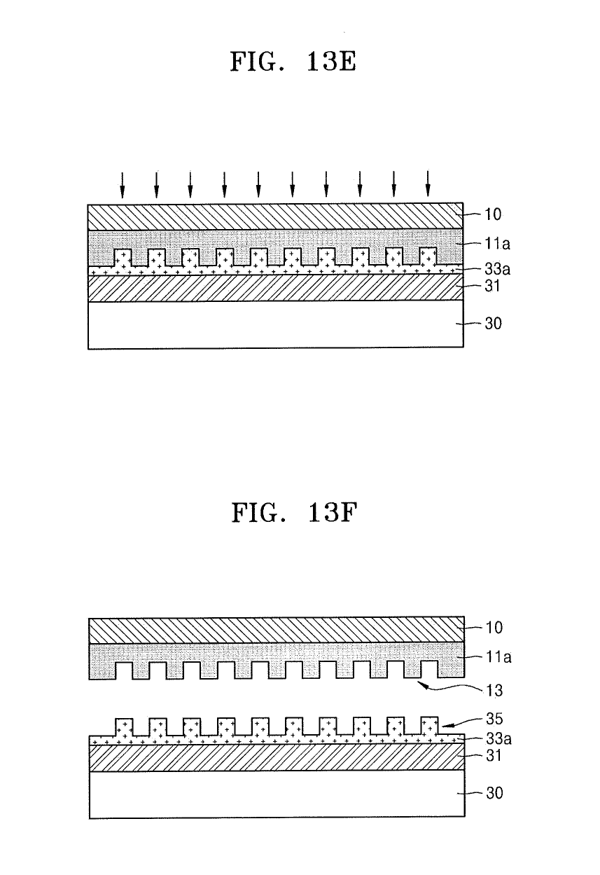

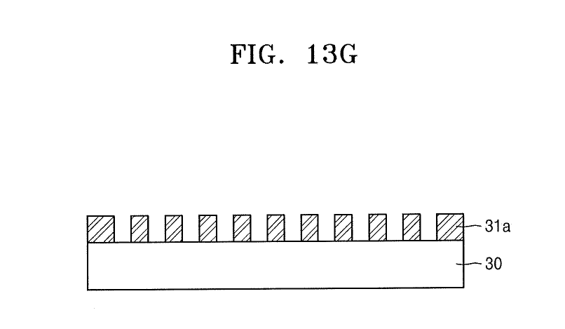

The curer 160 may cure a second resin layer (see 33a of FIG. 13E) between the flexible substrate 10 and the substrate 30 during the imprint process. In an implementation, the curer 160 may include an ultraviolet (UV) curer or a thermal curer.

In an implementation, the curer 160 may perform a curing process while moving along behind or following the pressure roller 150. For example, while the pressure roller 150 is moved in the first direction D1 and simultaneously presses the flexible substrate 10, the curer 160 may cure the resin layer arranged between the flexible substrate 10 and the substrate 30 while following the pressure roller 150. Thus, a portion of the resin layer pressed first by the pressure roller 150 may be locally cured, and then, curing of the resin layer may be sequentially performed along the first direction D1 that is a moving direction of the pressure roller 150.

If more tension than is needed were to be applied to the flexible substrate 10 in the process section PS, distortion of a transferred pattern due to deformation of the flexible substrate 10 could occur, and undesirable detachment of the flexible substrate 10 from the substrate 30 without being maintained in contact with the substrate 30 may result. In addition, if the tension applied to the flexible substrate 10 in the process section PS were to be too low, the flexible substrate 10 could sag in the direction of gravity, and the flexible substrate 10 could be brought into contact with the substrate 30 before arrival of the pressure roller 150. In this case, as the air flowing between the flexible substrate 10 and the substrate 30 may not be discharged, and a void-like defect in which a pattern is not locally transferred could occur.

In the imprint apparatus 100 according to an embodiment, a desired level of tension may be precisely applied to the flexible substrate 10 in the limited process section PS by using the clamp 130, and a nano-sized pattern may be extremely uniformly transferred in a large-area imprint process.

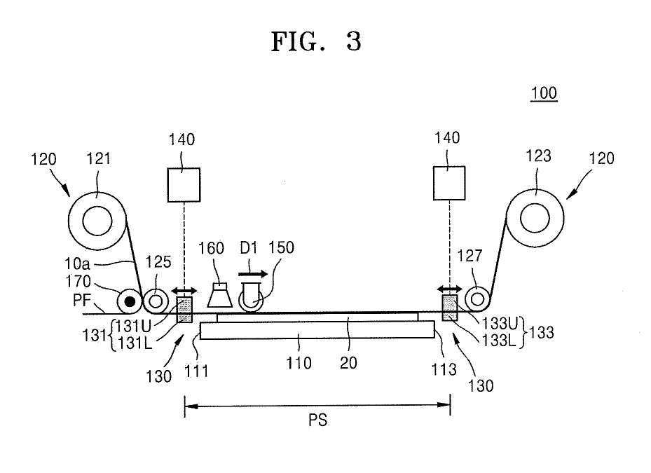

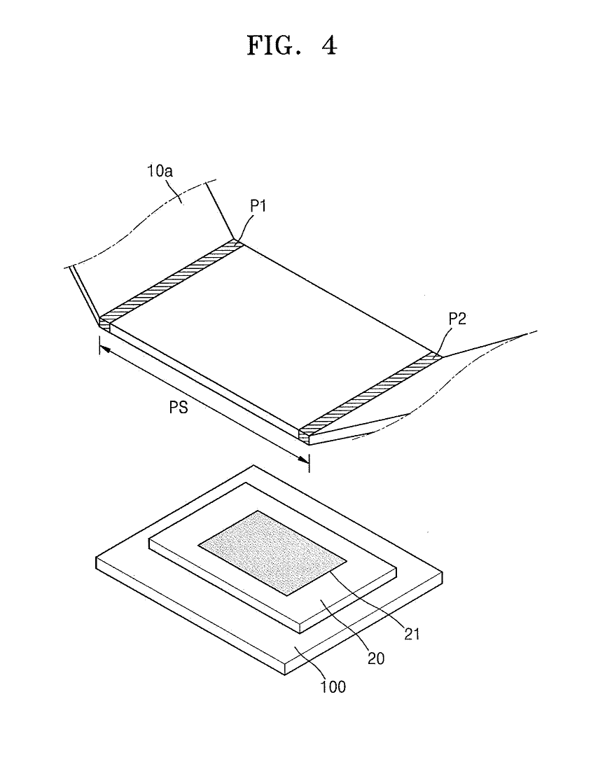

FIG. 3 illustrates a schematic diagram of the imprint apparatus 100 according to some embodiments. FIG. 4 illustrates a perspective view of a stamp master 20 and the flexible substrate 10a that is secured by the clamp 130, during a mold stamp process in the imprint apparatus 100 shown in FIG. 3. In FIG. 4, the flexible substrate 10a and the stamp master 20 are separately illustrated for convenience.

Referring to FIGS. 3 and 4, the imprint apparatus 100 may perform a film stamp process for forming a stamping pattern on the flexible substrate 10a. Unlike in the imprint process, the stage 110 may support the stamp master 20 on which a master pattern 21 is formed, and the roll-to-roll mover 120 may move the flexible substrate 10a so that a portion of the flexible substrate 10a, on which the stamping pattern is to be formed, is located over the stamp master 20.

When the film stamp process is performed, the front clamp 131 and the rear clamp 133 may respectively secure the first portion P1 and the second portion P2, which are both ends of a certain region of the flexible substrate 10a. Here, the region of the flexible substrate 10a between the first portion P1 and the second portion P2 may refer to a region for forming the stamping pattern by transferring the master pattern 21 of the stamp master 20.

Like in the description made with reference to FIGS. 1A to 2, the flexible substrate 10a may be sequentially brought into contact with the stamp master 20 by the pressure roller 150 moving in the first direction D1, and a resin layer (see 11a of FIG. 13B) between the flexible substrate 10a and the stamp master 20 may be cured by the curing member 160 moving following the pressure roller 150. As a result, the master pattern 21 of the stamp master 20 may be transferred to the region of the flexible substrate 10a. As described above, in the imprint apparatus 100 according to an embodiment, a desired level of tension may be precisely applied to the flexible substrate 10a within the process section PS by using the clamp 130, and the master pattern 21 of the stamp master 20 may be extremely uniformly transferred to the flexible substrate 10a.

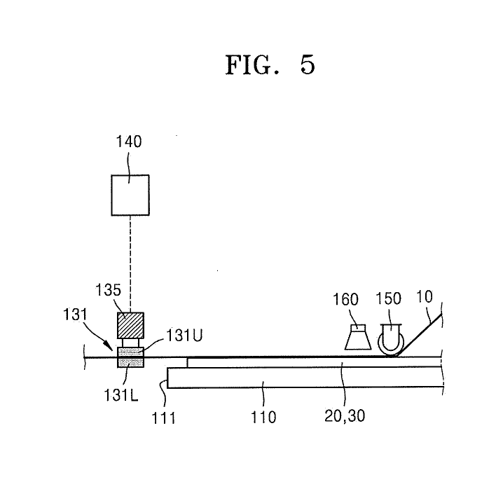

FIG. 5 illustrates a schematic diagram of a portion of the imprint apparatus 100 shown in FIGS. 1A and 1B.

Referring to FIG. 5 together with FIGS. 1A to 2, a tension sensor 135 for measuring the tension applied between the first portion P1 (secured by the front clamp 131) and the second portion P2 (secured by the rear clamp 133) may be mounted to the clamp 130. The tension sensor 135 may be mounted to at least one of the front clamp 131 and the rear clamp 133.

In an implementation, the clamp driving controller 140 may generate a feedback signal for adjusting the tension between the first portion P1 and the second portion P2 in real time, based on information measured by the tension sensor 135 mounted to the front clamp 131 and the rear clamp 133. The clamp driving controller 140 may drive the front clamp 131 and the rear clamp 133 in real time by using the feedback signal, thereby controlling the tension of the flexible substrate 10 within the process section PS in real time.

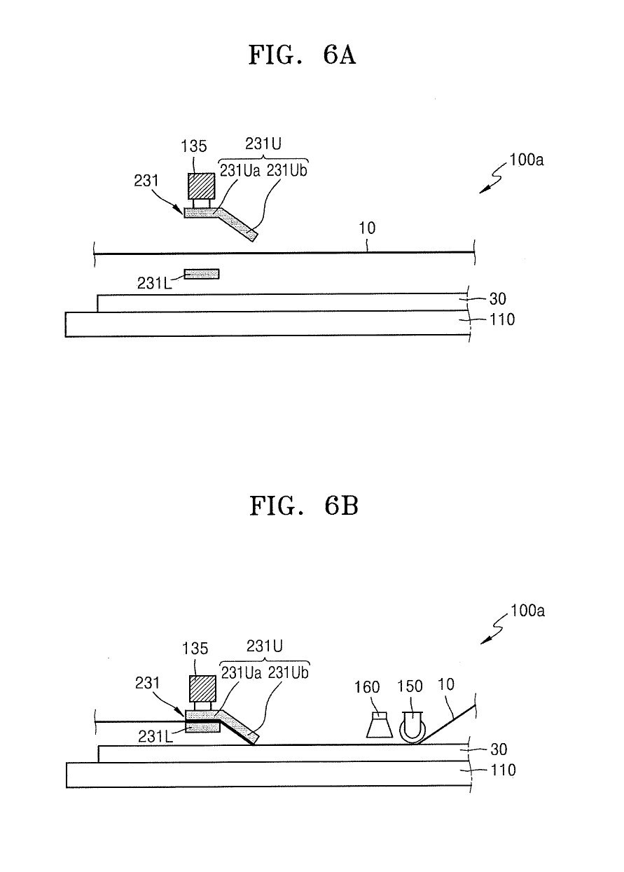

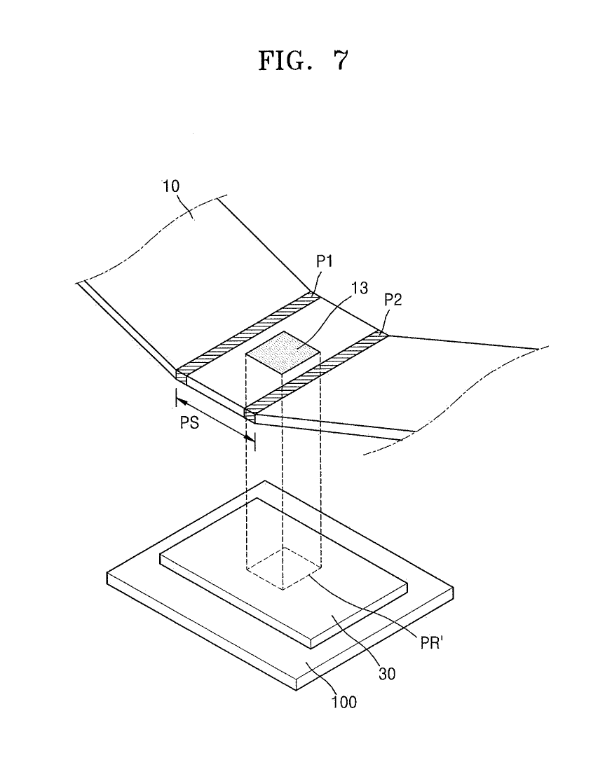

FIGS. 6A and 6B illustrate schematic diagrams of a portion of an imprint apparatus 100a according to some embodiments. FIG. 7 illustrates a perspective view of the substrate and the flexible substrate 10 that is secured by the clamp, in the imprint apparatus 100a shown in FIG. 6B. FIG. 6A illustrates the imprint apparatus 100a when the clamp for securing the flexible substrate 10 is opened, and FIG. 6B illustrates the imprint apparatus 100a when the flexible substrate 10 is secured by the clamp. In FIG. 7, the flexible substrate 10 and the substrate 30 are separately illustrated for convenience.

The imprint apparatus 100a shown in FIGS. 6A to 7 may have a substantially identical configuration to the imprint apparatus 100 shown in FIGS. 1A to 5 except a structure of a front clamp 231.

Referring to FIGS. 6A to 7, during the imprint process, the front clamp 231 may secure the first portion P1 of the flexible substrate 10 at a position vertically spaced apart from the substrate 30 or the stage 110 by a certain distance. For example, in the imprint process, the front clamp 231 may secure the first portion P1 of the flexible substrate 10 at a position spaced apart upwards from the substrate 30 by a certain distance to avoid contact with the substrate 30. In an implementation, the front clamp 231 may guide a portion of the flexible substrate 10 in the vicinity of the first portion P1 downwards to a position adjacent to one end of a pattern region PR′.

For example, the front clamp 231 may include a first upper body 231U and a first lower body 231L spaced apart from each other with the flexible substrate 10 therebetween, and the first upper body 231U may include a clamping part or clamper 231Ua and a guide part or guide 231Ub.

The clamper 231Ua may secure the first portion P1 of flexible substrate 10 in cooperation with the first lower body 231L.

The guide 231Ub may downwardly guide the portion of the flexible substrate 10 in the vicinity of the first portion P1 of the flexible substrate 10 secured by the clamper 231Ua. The guide 231Ub may extend in a direction inclined with respect to an extension direction of the clamping part 231Ua.

As shown in FIG. 6B, the guide 231Ub may extend from the damper 231Ua in the inclined direction and guide the flexible substrate 10 to the one end of the pattern region PR′ of the substrate 30. The flexible substrate 10 guided by the guide 231Ub may be brought into contact with the substrate 30, starting with contact with the one end of the pattern region PR′, the imprint process may be performed by bringing the flexible substrate 10 into contact with only a desired region of the substrate 30, and the flexible substrate 10 may be prevented from being unnecessarily brought into contact with regions other than the pattern region PR′.

In this case, the pressure roller 150 may stand by at a position spaced apart from the substrate 30 by a certain distance before the first portion P1 of the flexible substrate 10 is secured by the front clamp 231, and when the first portion P1 of the flexible substrate 10 is secured by the front clamp 231, the pressure roller 150 may be lowered so that the flexible substrate 10 contacts a region in the vicinity of the one end of the pattern region PR′, thereby bringing the flexible substrate 10 into contact with the region in the vicinity of the one end of the pattern region PR′ and pressing the flexible substrate 10. Next, the pressure roller 150 may sequentially press the flexible substrate 10 while horizontally moving in the first direction, as described above. In addition, the curer 160 may perform the curing process while moving in downward and horizontal directions following the pressure roller 150.

In an implementation, the imprint process for forming a pattern on the substrate 30 may be performed as described with reference to FIGS. 6A to 7, or the imprint apparatus 100a including the front clamp 231 substantially identical to that described with reference to FIGS. 6A to 7 may also be used in the film stamp process.

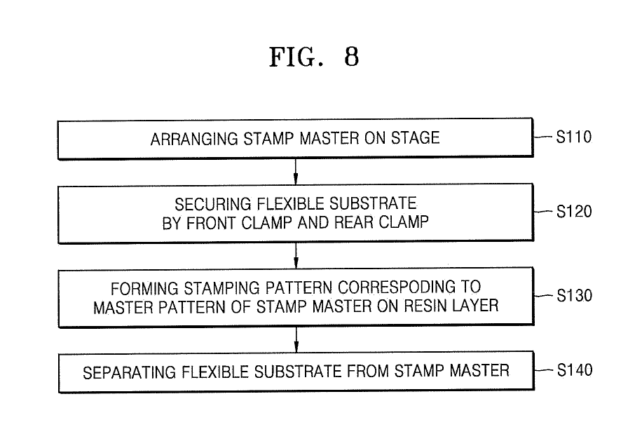

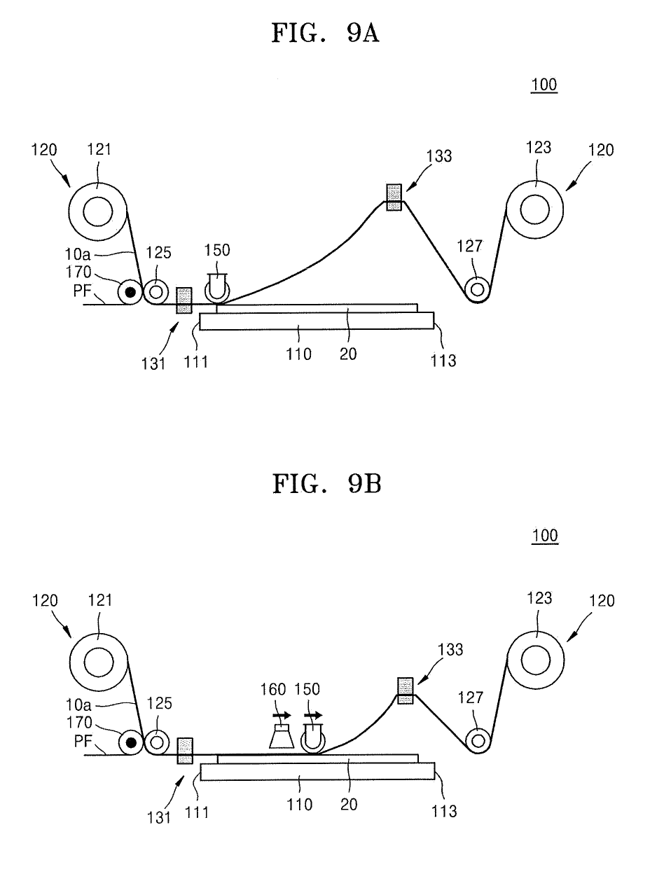

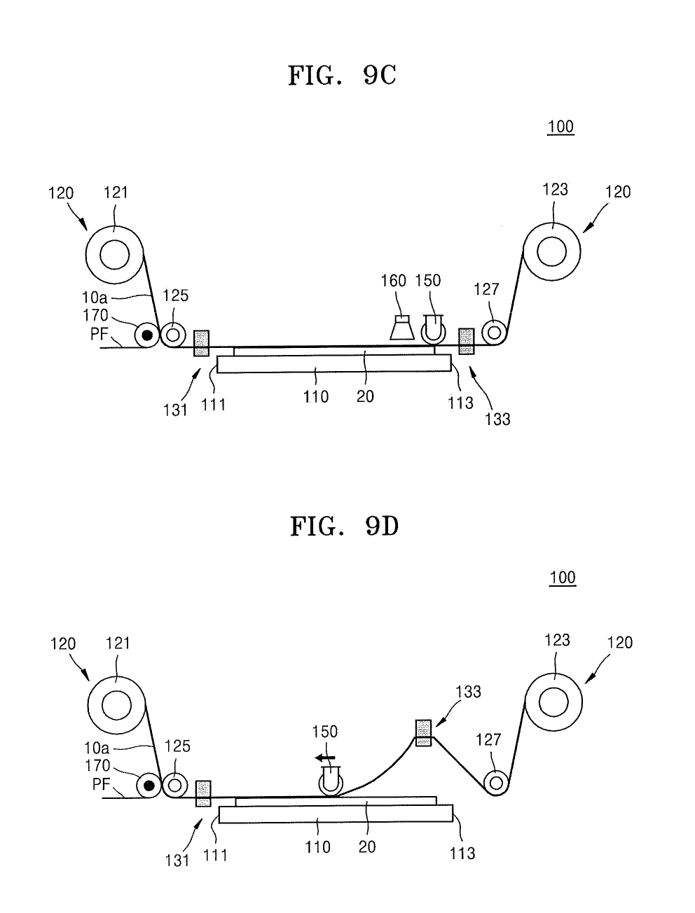

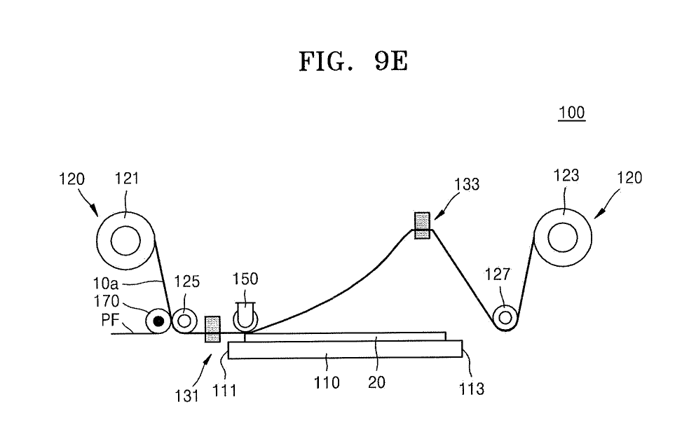

FIG. 8 illustrates a flowchart of the film stamp process for forming the stamping pattern 13 on the flexible substrate 10 by using the imprint apparatus 100 according to some embodiments. FIGS. 9A to 9E illustrate diagrams showing stages in a film stamp process using the imprint apparatus 100 according to some embodiments.

Referring to FIGS. 8 and 9A, the stamp master 20, on which the master pattern is formed, may be arranged on the stage 110 (S110). A first resin layer (see 11 of FIG. 13A) may be coated on the stamp master 20. The roll-to-roll mover 120 may move the flexible substrate 10 so that a certain region of the flexible substrate 10 is located over the stage 110. Here, the certain region of the flexible substrate 10 is a region to which the master pattern of the stamp master 20 is to be transferred.

Next, the first portion (P1 of FIG. 2) and the second portion (P2 of FIG. 2) of the flexible substrate 10 may be respectively secured by using the front clamp 131 and the rear clamp 133 (S120). The front clamp 131 may be arranged adjacent to the one end 111 of the stage 110. The front clamp 131 may be stopped while securing the first portion P1 of the flexible substrate 10, during the process of contact and separation between the flexible substrate 10 and the stamp master 20. The rear clamp 133 may secure the second portion P2 of the flexible substrate 10 at a position vertically spaced apart from the stage 110 by a certain distance so that the flexible substrate 10 is not brought into contact with the substrate 30 before being pressed by the pressure roller 150.

In an implementation, the front clamp 131 may be arranged to be spaced apart from the one end 111 of the stage 110 in a peripheral or lateral direction of the stage 110. In an implementation, the front clamp 131 may secure the flexible substrate 10 at a position spaced apart upwardly from the substrate 30 or the stage 110 by a certain distance.

Referring to FIGS. 8, 9B, and 9C, the flexible substrate 10 may be brought into contact with the stamp master 20 by the pressure roller 150, whereby the stamping pattern 13 corresponding to the master pattern of the stamp master 20 is formed on the resin layer (see 11a of FIG. 13B) arranged between the flexible substrate 10 and the stamp master 20 (S130).

The pressure roller 150 may press the flexible substrate 10 while moving in one direction, e.g., in a first direction from the one end 111 of the stage 110 toward the other end 113 of the stage 110, thereby sequentially bringing the flexible substrate 10 into contact with the stamp master 20. The curer 160 may sequentially cure the resin layer, which is arranged between the flexible substrate 10 and the stamp master 20, along the first direction while moving following the pressure roller 150 moving in the first direction.

The clamp driving controller (140 of FIG. 1A) may move the rear clamp 133 downwardly from an initial position in association with the movement of the pressure roller 150 in the first direction. A vertical position and/or a horizontal position of the rear clamp 133 may be adjusted so that a certain portion of the flexible substrate 10 is not brought into contact with the stamp master 20 in advance before arrival of the pressure roller 150.

In addition, in association with the movement of the rear clamp 133, the flexible substrate recovering roll 123 may perform a rewinding operation so that a length of the flexible substrate 10 between the rear clamp 133 and the flexible substrate recovering roll 123 is appropriately adjusted.

Referring to FIGS. 8, 9D, and 9E, the flexible substrate 10 may be separated from the stamp master 20 (S140).

To sequentially separate the flexible substrate 10 from the stamp master 20, the clamp driving controller (140 of FIG. 1A) may move the rear clamp 133 (securing the second portion P2 of the flexible substrate 10) upwardly while the front clamp 131 securing the first portion P1 of the flexible substrate 10 is stopped. For example, as the rear clamp 133 is moved upwardly while securing the second portion P2 of the flexible substrate 10, the flexible substrate 10 may be separated from the stamp master 20 along a second direction opposite to the first direction.

In association with the upward movement of the rear clamp 133, the flexible substrate recovering roll 123 may perform an unwinding operation so that the length of the flexible substrate 10 between the rear clamp 133 and the flexible substrate recovering roll 123 is appropriately adjusted.

The pressure roller 150 may guide the flexible substrate 10 so that the flexible substrate 10 is sequentially separated from the stamp master 20. For example, the pressure roller 150 may be moved in the second direction opposite to the first direction in association with the upward movement of the rear clamp 133.

In an implementation, a relative position of the rear clamp 133 with respect to the pressure roller 150 may be adjusted to more easily perform separation of the flexible substrate 10. For example, the relative position of the rear clamp 133 with respect to the pressure roller 150 is adjusted, whereby a separation angle, e.g., an angle at which a portion of the flexible substrate 10 between the pressure roller 150 and the rear clamp 133 tilted with respect to the main surface of the stage 110 may be adjusted. The relative position of the rear clamp 133 with respect to the pressure roller 150 may be adjusted so that the separation angle is maintained within a more suitable range for performing the separation.

When the film stamp process is completed by separating the flexible substrate 10 from the stamp master 20, the stamping pattern 13 corresponding to the master pattern of the stamp master 20 may be formed on the resin layer (see 11a of FIG. 13C) under the flexible substrate 10.

To form a second stamping pattern on another region of the flexible substrate 10 after a first stamping pattern is formed through the processes described with reference to FIGS. 9A to 9E, the front clamp 131 and the rear clamp 133 may release the flexible substrate 10 from being secured, and the roll-to-roll mover 120 may unwind or rewind the flexible substrate 10 so that a certain region of the flexible substrate 10 not subjected to pattern formation is located over the stage 110. Next, the second stamping pattern may be formed on the flexible substrate 10 through substantially identical processes to those described above with reference to FIGS. 9A to 9E.

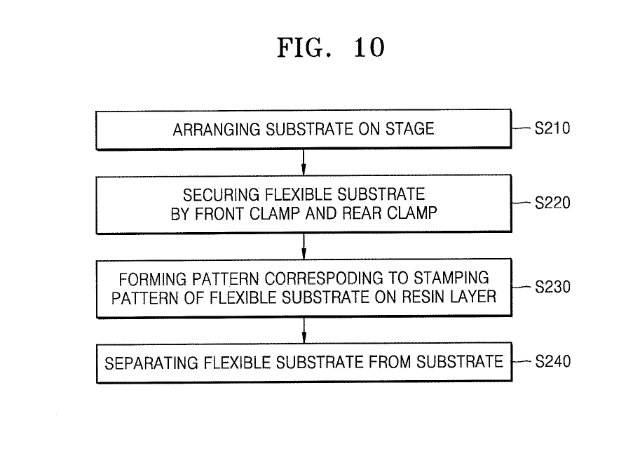

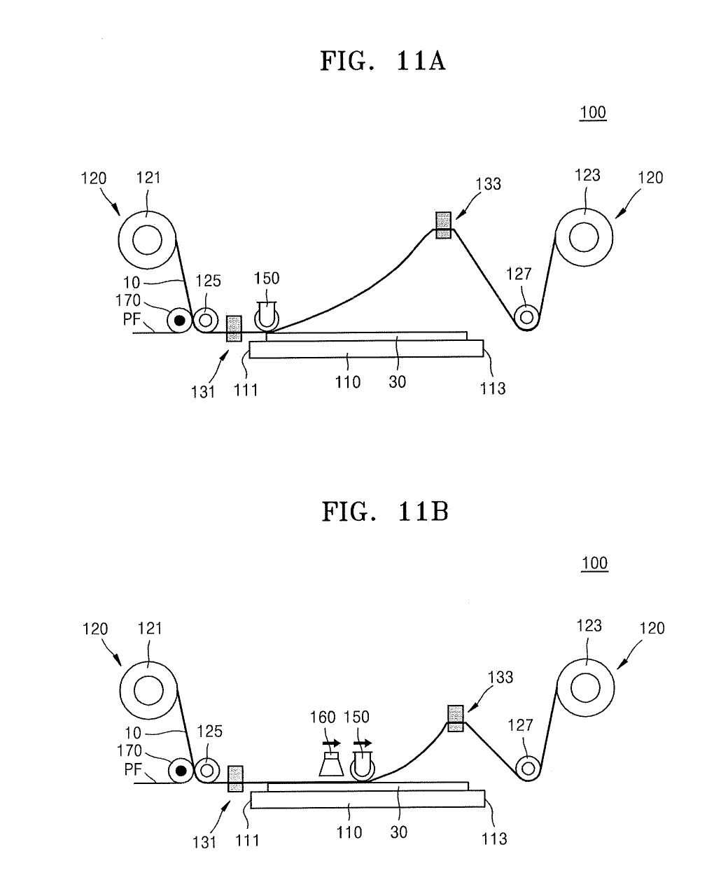

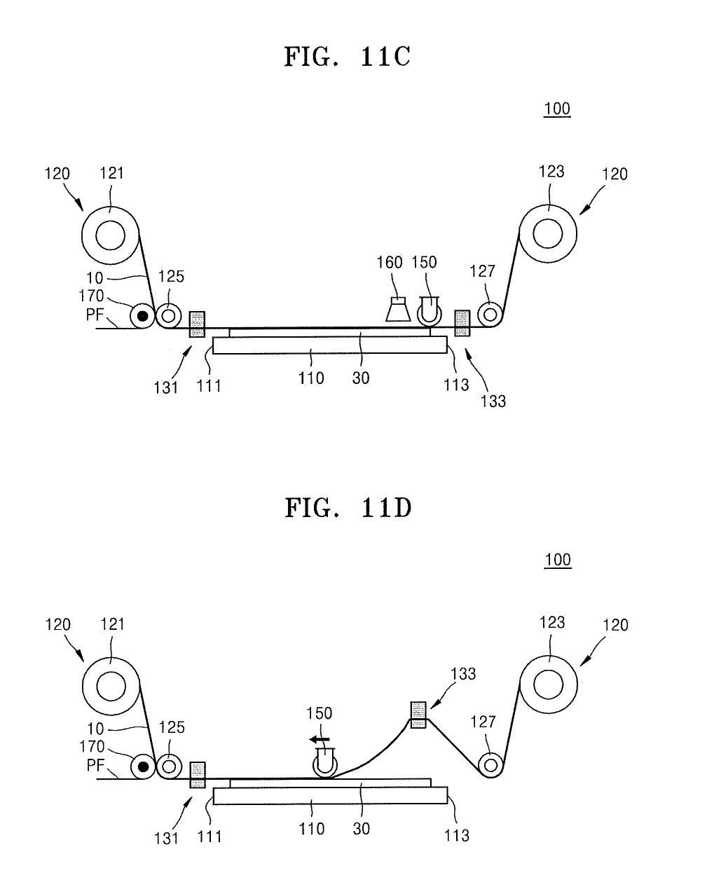

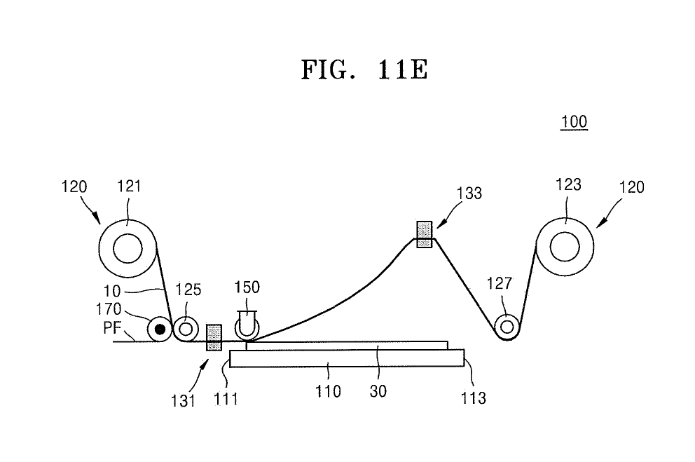

FIG. 10 illustrates a flowchart of the imprint process for transferring the stamping pattern 13 of the flexible substrate 10 to the substrate 30 by using the imprint apparatus 100 according to some embodiments. FIGS. 11A to 11E illustrate diagrams of stages in the imprint process using the imprint apparatus 100 according to some embodiments.

Referring to FIGS. 10 and 11A, the substrate 30, which is a pattern transfer object, may be arranged on the stage 110 (S210). A second resin layer (see 33 of FIG. 13D) may be coated on the substrate 30. The roll-to-roll mover 120 may move the flexible substrate 10 so that a certain region of the flexible substrate 10, on which the stamping pattern 13 has been formed, is located over the stage 110.

Next, the first portion (P1 of FIG. 2) and the second portion (P2 of FIG. 2) of the flexible substrate 10 may be respectively secured by using the front clamp 131 and the rear clamp 133 (S220). The front clamp 131 may be stopped while securing the first portion P1 of the flexible substrate 10, during the process of contact and separation between the flexible substrate 10 and the stamp master 20. The rear clamp 133 may secure the second portion P2 of the flexible substrate 10 while vertically spaced apart from the stage 110 by a certain distance.

Referring to FIGS. 10, 11B, and 11C, the flexible substrate 10 may be brought into contact with the substrate 30 by the pressure roller 150, whereby a pattern corresponding to the stamping pattern 13 of the flexible substrate 10 may be formed on the second resin layer (see 33a of FIG. 13E) arranged between the flexible substrate 10 and the substrate 30 (S230).

The pressure roller 150 may press the flexible substrate 10 while moving in one direction, e.g., in the first direction from the one end 111 of the stage 110 toward the other end 113 of the stage 110, thereby sequentially bringing the flexible substrate 10 into contact with the substrate 30. The curer 160 may sequentially cure the resin layer, which is arranged between the flexible substrate 10 and the substrate 30, in the first direction while moving following the pressure roller 150 moving in the first direction.

The clamp driving controller (140 of FIG. 1A) may move the rear clamp 133 downwardly from the initial position in association with the movement of the pressure roller 150 in the first direction. The vertical position and/or the horizontal position of the rear clamp 133 may be adjusted so that a certain portion of the flexible substrate 10 is not brought into contact with the substrate 30 in advance or before arrival of the pressure roller 150.

In addition, in association with the movement of the rear clamp 133, the flexible substrate recovering roll 123 may perform a rewinding operation so that the length of the flexible substrate 10 between the rear clamp 133 and the flexible substrate recovering roll 123 is appropriately adjusted.

Referring to FIGS. 10, 11D, and 11E, the flexible substrate 10 is separated from the substrate 30 (S240).

To sequentially separate the flexible substrate 10 from the substrate 30, the clamp driving controller (140 of FIG. 1A) may move the rear clamp 133 (securing the second portion P2 of the flexible substrate 10) upwardly while the front clamp 131 (securing the first portion P1 of the flexible substrate 10) is stopped. For example, as the rear clamp 133 is moved upwardly while securing the second portion P2 of the flexible substrate 10, the flexible substrate 10 may be separated from the substrate 30 along the second direction opposite to the first direction.

In association with the upward movement of the rear clamp 133, the flexible substrate recovering roll 123 may perform an unwinding operation so that the length of the flexible substrate 10 between the rear clamp 133 and the flexible substrate recovering roll 123 is appropriately adjusted.

The pressure roller 150 may guide the flexible substrate 10 so that the flexible substrate 10 is sequentially separated from the substrate 30. For example, the pressure roller 150 may be moved in the second direction opposite to the first direction in association with the upward movement of the rear clamp 133. In an implementation, the relative position of the rear clamp 133 with respect to the pressure roller 150 may be adjusted to be suitable for facilitating performing separation of the flexible substrate 10.

When the imprint process is completed by separating the flexible substrate 10 from the substrate 30, the pattern corresponding to the stamping pattern 13 of the flexible substrate 10 may be formed on the second resin layer (see 33a of FIG. 13F) on the substrate 30.

To transfer the second stamping pattern to the substrate 30 after the pattern corresponding to the first stamping pattern of the flexible substrate 10 is formed on the substrate 30 through the processes described with reference to FIGS. 11A to 11E, the front clamp 131 and the rear clamp 133 may release the flexible substrate 10 from being secured, and the roll-to-roll mover 120 may unwind or rewind the flexible substrate 10 so that the second stamping pattern of the flexible substrate 10 is located over the stage 110. Next, a pattern corresponding to the second stamping pattern may be formed on the substrate 30 through substantially identical processes to those described above with reference to FIGS. 11A to 11E.

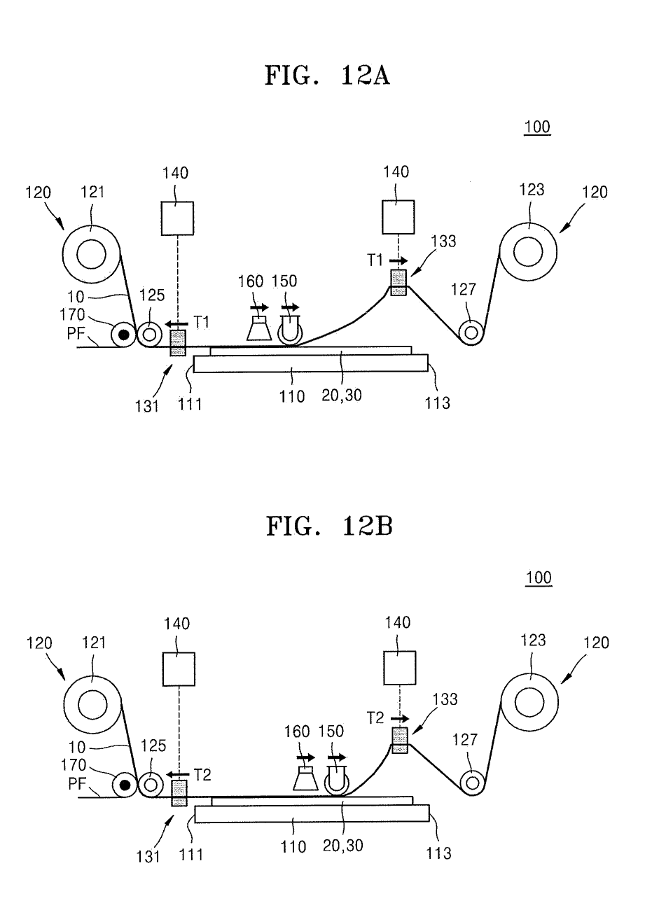

FIGS. 12A and 12B illustrate diagrams of stages in a method of operating the imprint apparatus 100 according to some embodiments.

Referring to FIGS. 12A and 12B, in the process of bringing the flexible substrate 10 into contact with the stamp master 20 by using the pressure roller 150 as shown in FIGS. 9A to 9C, or in the process of bringing the flexible substrate 10 into contact with the substrate 30 by using the pressure roller 150 as shown in FIGS. 11A to 11C, the clamp driving controller 140 may adjust the tension applied to the flexible substrate 10 within the process section in real time by driving the front clamp 131 and the rear clamp 133, as described above. Here, the clamp driving controller 140 may control the tension between the first portion (P1 of FIG. 2) and the second portion (P2 of FIG. 2) depending upon a positional change of the pressure roller 150 moving in the first direction.

In an implementation, as the pressure roller 150 moving in the first direction gets closer to the other end 113 of the stage 110, the tension between the first portion P1 and the second portion P2 may be reduced. For example, in FIG. 12A, the clamp driving controller 140 may drive the front clamp 131 and the rear clamp 133 so that a first tension T1 is applied between the first portion P1 and the second portion P2, and in FIG. 12B illustrating that the pressure roller is slightly closer to the other end 113 of the stage 110, the clamp driving controller 140 may drive the front clamp 131 and the rear clamp 133 so that a second tension T2 (less than the first tension T1) is applied between the first portion P1 and the second portion P2.

As the pressure roller 150 gets closer to the other end 113 of the stage 110, a portion of the flexible substrate 10 in non-contact with (e.g., spaced apart from) the substrate 30 or the stamp master 20, e.g., a portion of the flexible substrate 10 between the pressure roller 150 and the rear clamp 133, is reduced in length, and minimum tension for preventing the flexible substrate 10 from being brought into contact with the substrate 30 or the stamp master 20 in advance before arrival of the pressure roller 150 is reduced. By reducing the tension applied to the flexible substrate 10 within the process section as the pressure roller 150 becomes closer to the other end 113 of the stage 110, a problem in that the flexible substrate 10 is brought into contact with the substrate 30 or the stamp master 20 in advance before arrival of the pressure roller 150 may be prevented.

Hereinafter, a method of manufacturing a display panel by using the imprint method described above will be described.

FIGS. 13A to 13G illustrate cross-sectional views of stages in a method of manufacturing a display panel, according to some embodiments.

Referring to FIG. 13A, the stamp master 20, on which the master pattern 21 is formed, may be prepared, and the first resin layer 11 may be coated on the stamp master 20. In an implementation, an anti-adhesion layer may be formed on a surface of the stamp master 20 having the master pattern 21 formed thereon. The first resin layer 11 may include a UV curable resin or a thermally curable resin, and may be coated on the surface of the stamp master 20 having the master pattern 21 by spin coating or dispensing.

Referring to FIG. 13B, the flexible substrate 10a may be brought into contact with the first resin layer 11a, a pressure may be applied to the first resin layer 11a, and the first resin layer 11 a may be cured by applying UV or heat to the first resin layer 11a. The stamping pattern (13 of FIG. 13C) corresponding to the master pattern (21 of FIG. 13C) may be formed on the first resin layer 11a that is cured. As shown in FIG. 13B, to form the stamping pattern 13 on the first resin layer 11a, processes substantially identical to those described with reference to FIGS. 9A to 9C may be performed.

Referring to FIG. 13C, the flexible substrate 10 may be separated from the stamp master 20. The flexible substrate 10 and the first resin layer 11 a that is cured may form one body. The stamping pattern 13 formed on the first resin layer 11 a may have a shape opposite or complementary to that of the master pattern 21 of the stamp master 20. As shown in FIG. 13C, to separate the flexible substrate 10 from the stamp master 20, processes substantially identical to those described with reference to FIGS. 9C to 9E may be performed.

Referring to FIG. 13D, the substrate 30, on which a first material film 31 and the second resin layer 33 on the first material film 31 are formed, may be prepared. For example, the first material film 31 may include a SiO₂ film or an SiN film. The second resin layer 33 may include a UV curable resin or a thermally curable resin. Next, a result product of FIG. 13C, e.g., the flexible substrate 10 having the stamping pattern 13 formed thereon, may be located over the substrate 30. In an implementation, the flexible substrate 10 manufactured by processes different from the processes of FIGS. 13A to 13C may be used.

Referring to FIG. 13E, the flexible substrate 10 may be brought into contact with the second resin layer 33a, a pressure may be applied to the second resin layer 33a, and the second resin layer 33a may be cured by applying UV or heat to the second resin layer 33a. A pattern (35 of FIG. 13F) corresponding to the stamping pattern (13 of FIG. 13F) may be formed on the second resin layer 33a that is cured. As shown in FIG. 13B, to form the pattern 35 on the second resin layer 33a, processes substantially identical to those described with reference to FIGS. 11A to 11C may be performed.

Referring to FIG. 13F, the flexible substrate 10 may be separated from the substrate 30. The pattern 35 formed on the second resin layer 33a may have a shape opposite or complementary to that of the stamping pattern 13 of the first resin layer 11 a. As shown in FIG. 13F, to separate the flexible substrate 10 from the substrate 30, processes substantially identical to those described with reference to FIGS. 11C to 11E may be performed.

Referring to FIG. 13G, a portion of the first material film 31a may be removed by using the pattern (35 of FIG. 13F) formed on the second resin layer (33a of FIG. 13F). To remove the portion of the first material film 31a, a dry etching process may be performed.

By way of summation and review, to perform a large-area nanoimprint process, a roll-to-roll type imprint apparatus, which is capable of continuously supplying a flexible mold, may have high productivity. However, in imprint apparatuses and imprint methods using these imprint apparatuses, tension applied to a flexible mold may not be precisely controlled, and a pattern transferred to a substrate may be non-uniformly formed.

According to the embodiments, since a nano-sized pattern may be extremely uniformly transferred in a large-area imprint process, the display panel, in which a fine pattern is precisely implemented on a substrate, may be manufactured. In addition, according to the embodiments, in forming a wire grid polarizer included in the display panel, a nanowire having a high aspect ratio may be formed, and the display panel having an improved polarization separation ratio may be manufactured. The embodiments may also provide a method of fabricating a semiconductor device by using an imprint process for pattern transfer.

The embodiments may provide an imprint apparatus that may precisely control tension applied to a flexible substrate in a mold stamp process or imprint process performed in a roll-to-roll manner.

The embodiments may provide an imprint method using the imprint apparatus set forth above and a method of manufacturing a display panel, the method including the imprint method set forth above.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. An imprint apparatus, comprising:
a stage, the stage supporting:
a stamp master on which a master pattern for forming a stamping pattern on a flexible substrate is formed, or
a substrate on which a pattern corresponding to the stamping pattern is formed by contact with the flexible substrate having the stamping pattern;
a roll-to-roll mover configured to move the flexible substrate along a path adjacent to the stage;
a clamp, the clamp including:
a front clamp that secures a first portion of the flexible substrate, and
a rear clamp that secures a second portion of the flexible substrate, the second portion being spaced apart from the first portion in a length direction of the flexible substrate;
a pressure roller configured to press the flexible substrate so that the flexible substrate secured by the clamp is brought into contact with the substrate or the stamp master; and
a clamp driving controller configured to drive the clamp to adjust tension between the first portion and the second portion.

2. The imprint apparatus according as claimed in claim 1, wherein the clamp driving controller is configured to move at least one of the front clamp while securing the first portion and the rear clamp while securing the second portion and to adjust the tension between the first portion and the second portion.

3. The imprint apparatus according as claimed in claim 1, wherein:
the front clamp includes an upper body and a lower body spaced apart from each other with the flexible substrate therebetween, and
the upper body includes:
a clamper securing the flexible substrate arranged between the upper body and the lower body in cooperation with the lower body, and
a guide extending from the clamper in a direction inclined with respect to an extension direction of the clamper and guiding the flexible substrate in the inclined direction.

4. The imprint apparatus according as claimed in claim 1, further comprising a tension sensor mounted to the clamp to measure the tension between the first portion and the second portion.

5. The imprint apparatus according as claimed in claim 4, wherein the clamp driving controller is configured to drive the clamp so that the tension between the first portion and the second portion is adjusted in real time, based on information measured by the tension sensor.

6. The imprint apparatus according as claimed in claim 1, wherein the pressure roller is configured to press the flexible substrate while moving in a first direction from one end of the stage toward the other end of the stage, the one end being opposite to the other end.

7. The imprint apparatus according as claimed in claim 6, wherein the clamp driving controller is configured to move the rear clamp downwardly in association with movement of the pressure roller in the first direction.

8. The imprint apparatus according as claimed in claim 6, wherein:
the clamp driving controller is configured to move the rear clamp upwardly while the front clamp is stopped, so that the flexible substrate is separated from the substrate or the stamp master, and
the pressure roller is configured to move in a second direction, opposite to the first direction, in association with the upward movement of the rear clamp.

9. The imprint apparatus according as claimed in claim 6, further comprising a curer that cures a resin layer arranged between the flexible substrate and the substrate or a resin layer arranged between the flexible substrate and the stamp master,
wherein the curer is configured to follow the pressure roller moving in the first direction.

10. The imprint apparatus according as claimed in claim 6, wherein the clamp driving controller is configured to drive the clamp such that the tension between the first portion and the second portion is reduced as the pressure roller moving in the first direction gets closer to the other end of the stage.

11. The imprint apparatus according as claimed in claim 1, wherein each of the front clamp and the rear clamp is a magnetic clamp.

12. An imprint apparatus, comprising:
a stage supporting a substrate having a pattern region;
a roll-to-roll mover configured to move a flexible substrate along a path adjacent to the stage;
a front clamp arranged adjacent to one end of the pattern region and securing a first portion of the flexible substrate; and
a rear clamp arranged adjacent to the other end of the pattern region opposite to the one end of the pattern region and securing a second portion of the flexible substrate, the second portion being spaced apart from the first portion,
wherein the front clamp includes a guide extending downwardly to guide the flexible substrate to a position adjacent to the one end of the pattern region.

13. The imprint apparatus according as claimed in claim 12, further comprising a pressure roller configured to press the flexible substrate so that the flexible substrate secured by the front clamp and the rear clamp is brought into contact with the substrate,
wherein, while the pressure roller presses the flexible substrate, at least one of the front clamp and the rear clamp is moved simultaneously while securing the flexible substrate such that tension between the first portion and the second portion is adjusted.

14. The imprint apparatus according as claimed in claim 12, further comprising:
a tension sensor mounted to at least one of the front clamp and the rear clamp and configured to measure tension between the first portion and the second portion; and
a clamp driving controller configured to control driving of the front clamp and the rear clamp in real time based on information measured by the tension sensor.

15. The imprint apparatus according as claimed in claim 12, wherein each of the front clamp and the rear clamp extends in a width direction of the flexible substrate, the width direction being orthogonal to a length direction of the flexible substrate.

16. An imprint apparatus, comprising:
a roll-to-roll unwinder/rewinder configured to unwind or rewind a flexible substrate;
a stage arranged under the flexible substrate supported by the roll-to-roll unwinder/rewinder, the stage supporting:
a stamp master, on which a master pattern for forming a stamping pattern on the flexible substrate is formed, or
a substrate, which is brought into contact with the flexible substrate having the stamping pattern formed thereon so that a pattern corresponding to the stamping pattern is formed on the substrate;
a front clamp securing a first end of a region of the flexible substrate;
a rear clamp securing a second end of the region of the flexible substrate, the second end being opposite to the first end; and
a pressure roller configured to press the flexible substrate while moving between the first end and the second end so that the flexible substrate is brought into contact with the substrate or the stamp master,
wherein, in correspondence with the movement of the pressure roller, the front clamp securing the first end is fixed at a certain position, and the rear clamp securing the second end is moved upwardly or downwardly.

17. The imprint apparatus as claimed in claim 16, wherein:
the pressure roller is configured to move in a first direction to press the flexible substrate, the first direction being from the first end toward the second end, and
the rear clamp is configured to move downwardly in correspondence with the movement of the pressure roller in the first direction.

18. The imprint apparatus as claimed in claim 16, wherein:
the rear clamp is configured to move upwardly while securing the second end, so that the flexible substrate is separated from the substrate or the stamp master, and
the pressure roller is configured to move in a direction from the second end toward the first end in correspondence with the upward movement of the rear clamp.

19. The imprint apparatus as claimed in claim 16, wherein:
the front clamp includes an upper body and a lower body, each extending along a width direction of the flexible substrate, and
the upper body includes:
a clamper vertically aligned with the lower body, and
a guide extending from the clamper in a length direction of the flexible substrate.

20. The imprint apparatus as claimed in claim 16, further comprising:
a tension sensor mounted to at least one of the front clamp and the rear clamp to measure tension between the first end and the second end; and
a clamp driving controller configured to control the tension between the first end and the second end in real time by moving the rear clamp securing the second end based on information measured by the tension sensor.

21. (canceled)

22. (canceled)

23. (canceled)

24. (canceled)

25. (canceled)

26. (canceled)

27. (canceled)
